(19) United States
(12) Patent Application Publication
(10) Pub. No.: US 2022/0085333 A1
(43) Pub. Date: Mar. 17, 2022

(54) PACKAGE STRUCTURE, DISPLAY PANEL AND DISPLAY DEVICE

(71) Applicants: Chengdu BOE Optoelectronics Technology Co., Ltd., Chengdu (CN); BOE Technology Group Co., Ltd., Beijing (CN)

(72) Inventors: Ping WEN, Beijing (CN); Yang ZENG, Beijing (CN); Zhiliang JIANG, Beijing (CN); Ge WANG, Beijing (CN); Baoke HE, Beijing (CN)

(21) Appl. No.: 17/419,687

(22) PCT Filed: Nov. 10, 2020
(86) PCT No.: PCT/CN2020/127790

§ 371 Date: Jun. 29, 2021

(30) Foreign Application Priority Data
Nov. 14, 2019 (CN) 201911115546.0

(51) Int. Cl. H01L 51/52

(52) U.S. Cl. CPC H01L 51/5275; H01L 51/5253

(57) ABSTRACT

Disclosed are a package structure, a display panel and a display apparatus, wherein same belong to the technical field of display. The package structure (100) comprises: a first inorganic layer (11) and a second inorganic layer (12), which cover an outer side of a light-emitting device (200) and are stacked. The first inorganic layer (11) is used for adjusting a light path of a first light ray from among light rays emitted by the light-emitting device (200), such that the first light ray interferes with a second light ray from among the light rays emitted by the light-emitting device (200), thereby improving the light intensity of emitted light rays passing through the package structure (100), and thus improving the light emission efficiency of the light-emitting device (200).

### CROSS REFERENCE TO RELATED APPLICATION

This application is a US national stage of international application No. PCT/CN2020/127790, filed on Nov. 10, 2020, which claims priority to Chinese Patent Application No. 201911115546.0, filed on Nov. 14, 2019 and entitled “PACKAGE STRUCTURE, DISPLAY PANEL AND DISPLAY APPARATUS”, the disclosures of which are herein incorporated by reference in their entireties.

### TECHNICAL FIELD

The present disclosure relates to the field of display technologies, and in particular to a package structure, a display panel and a display device.

### BACKGROUND

Organic light-emitting diode (OLED) devices have advantages such as all-solid-state structure, high illumination, full viewing angle, high response speed and flexible display, which are thereof widely used in the display industry.

### SUMMARY

An embodiment of the present disclosure provides a package structure, a display panel and a display device.

According to a first aspect of the present disclosure, a package structure is provided. The package structure includes a first inorganic layer and a second inorganic layer that are stacked and cover an outer side of a light emitting element, wherein the first inorganic layer is distal from the light emitting element relative to the second inorganic layer, a thickness of the first inorganic layer is less than a thickness of the second inorganic layer, and a refractive index of the first inorganic layer is less than a refractive index of the second inorganic layer;

the first inorganic layer is configured to cause a path difference between first light and second light to be about an integral multiple of a target wavelength, the first light is light that is emitted from the package structure in response to being reflected inside the package structure among light emitted from the light emitting element, and the second light is light emitted from the package structure without being reflected inside the package structure among light emitted from the light emitting element, a wavelength of the first light and a wavelength of the second light being both the target wavelength.

Optionally, the first light and the second light are both blue light.

Optionally, the refractive index of the first inorganic layer is in a range of [1.3, 1.7], and the refractive index of the second inorganic layer is in a range of [1.6, 1.9].

Optionally, the thickness of the first inorganic layer is in a range from 20 nm to 120 nm, and the thickness of the second inorganic layer is in a range from 500 nm to 1000 nm.

Optionally, the package structure further includes a third inorganic layer and an organic layer that are laminated and cover the outer side of the light emitting element, wherein the third inorganic layer is proximal to the light emitting element relative to the organic layer, and the organic layer is proximal to the light emitting element relative to the second inorganic layer.

Optionally, a refractive index of the third inorganic layer is greater than a refractive index of the organic layer and less than a refractive index of the second inorganic layer.

Optionally, the first inorganic layer is made of silicon oxynitride, and the second inorganic layer is made of silicon nitride.

Optionally, the third inorganic layer is made of silicon oxynitride.

Optionally, the first light and the second light are both blue light;

the refractive index of the first inorganic layer is in a range of [1.3, 1.7], and the refractive index of the second inorganic layer is in a range of [1.6, 1.9];

the thickness of the first inorganic layer is in a range from 20 nm to 120 nm, and the thickness of the second inorganic layer is in a range from 500 nm to 1000 nm; and

the package structure further includes a third inorganic layer and an organic layer that are laminated and cover the outer side of the light emitting element, the third inorganic layer is proximal to the light emitting element relative to the organic layer, and the organic layer is proximal to the light emitting element relative to the second inorganic layer; and

a refractive index of the third inorganic layer is greater than a refractive index of the organic layer and less than a refractive index of the second inorganic layer.

According to another aspect of the present disclosure, a display panel is provided. The display panel includes a substrate, a light emitting element disposed on the substrate and a package structure covering an outer side of the light emitting element, and the package structure is the package structure according to any of the above aspects.

Optionally, the display panel further includes a connection film layer disposed between the light emitting element and the package structure.

Optionally, the package structure includes a third inorganic layer, an organic layer, a second inorganic layer and a first inorganic layer that sequentially cover the outer side of the light emitting element along a direction away from the substrate, the third inorganic layer is proximal to the light emitting element relative to the organic layer and a refractive index of the third inorganic layer is greater than a refractive index of the connection film layer.

Optionally, the refractive index of the third inorganic layer is greater than a refractive index of the organic layer and less than a refractive index of the second inorganic layer.

Optionally, the first inorganic layer is made of silicon oxynitride, the second inorganic layer is made of silicon nitride, and the third inorganic layer is made of silicon oxynitride.

Optionally, the third inorganic layer, the second inorganic layer and the first inorganic layer are formed by chemical vapor deposition.

Optionally, the organic layer is formed by an ink-jet printing process.

Optionally, the connection film layer is made of lithium fluoride.

Optionally, the light emitting element includes an organic light emitting diode.

Optionally, the display panel further includes a connection film layer disposed between the light emitting element and the package structure;

the package structure includes a third inorganic layer, an organic layer, a second inorganic layer and a first inorganic layer that sequentially cover the outer side of the light emitting element along a direction distal from the substrate, the third inorganic layer is proximal to the light emitting element relative to the organic layer and a refractive index of the third inorganic layer is greater than a refractive index of the connection film layer; and

the refractive index of the third inorganic layer is greater than a refractive index of the organic layer and less than a refractive index of the second inorganic layer.

According to still another aspect of the present disclosure, a display device is provided. The display device includes the display panel according to any of the above aspects.

### BRIEF DESCRIPTION OF THE DRAWINGS

To describe the technical solutions in the embodiments of the present disclosure more clearly, the following briefly introduces accompanying drawings required for describing the embodiments. Apparently, the accompanying drawings in the following description show merely some embodiments of the present disclosure, and a person of ordinary skill in the art may still derive other drawings from these accompanying drawings without creative efforts.

FIG. 1 is a structural schematic diagram of a package structure according to an embodiment of the present disclosure;

FIG. 2 is a path diagram of light that is emitted from a light emitting element and transmitted in the package structure shown in FIG. 1 according to an embodiment of the present disclosure;

FIG. 3 is a structural schematic diagram of a package structure according to another embodiment of the present disclosure;

FIG. 4 is a structural schematic diagram of a display panel according to an embodiment of the present disclosure;

FIG. 5 is a comparative diagram of a relationship curve between a color deviation degree of a display panel and a viewing angle according to an embodiment of the present disclosure and a relationship curve between a color deviation degree of a display panel and a viewing angle in the related art; and

FIG. 6 is a structural schematic diagram of a display device according to an embodiment of the present disclosure.

### DETAILED DESCRIPTION

For clearer descriptions of the objectives, technical solutions, and advantages of the present disclosure, embodiments of the present disclosure are described in detail hereinafter with reference to the accompanying drawings.

Since components such as water and oxygen in the air greatly affect service life of the OLED device, it is usually required to package the OLED device with a package structure so as to isolate the OLED device from the components such as water and oxygen in the air, thereby prolonging the service life of the OLED device.

At present, a package structure may include a plurality of package film layers that cover an outer side of an OLED device, and the plurality of package film layers include inorganic layers and organic layers superposed alternately.

However, when light emitted from the OLED device passes through the package structure, reflection and refraction occur between the package film layers. When the light is reflected and refracted, there is a problem of light energy loss, resulting in a low light emitting efficiency of the OLED device.

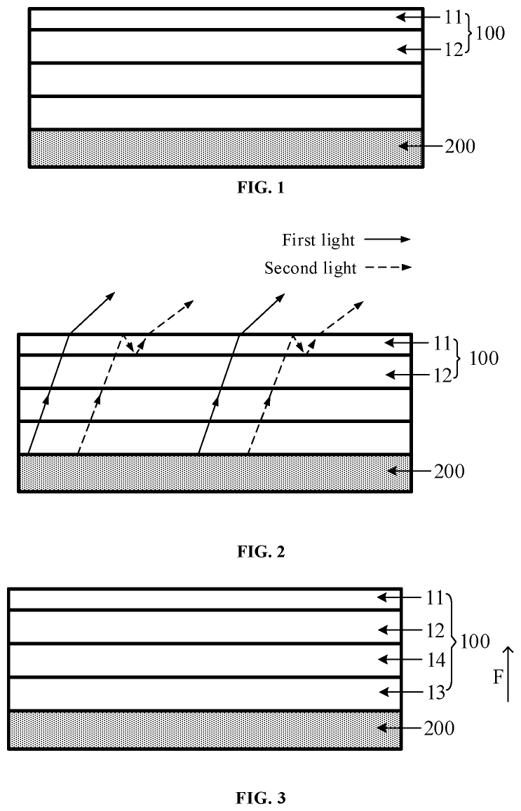

An embodiment of the present disclosure provides a package structure, the package structure is configured to package a light emitting element, and the light emitting element may be an organic light-emitting diode (OLED) device. FIG. 1 is a structural schematic diagram of a package structure according to an embodiment of the present disclosure. The package structure 100 may include a first inorganic layer 11 and a second inorganic layer 12 that are laminated and cover an outer side of a light emitting element 200. The first inorganic layer 11 is distal from the light emitting element 200 relative to the second inorganic layer 12. A thickness of the first inorganic layer 11 is less than a thickness of the second inorganic layer 12, and a refractive index of the first inorganic layer 11 is less than a refractive index of the second inorganic layer 12.

In an embodiment of the present disclosure, the first inorganic layer 11 is configured to adjust a path of first light, such that a path difference between the first light and second light is about an integral multiple of a target wavelength (optionally, the path difference between the first light and the second light is about 0.8-1.2 times of the target wavelength). At this time, the first light and the second light satisfy an interference condition, and may interfere constructively.

In a wave superposition principle, if peaks (or troughs) of two waves reach a same point simultaneously, it is called that two waves are in phase at this point, and an interference wave produces the maximum amplitude, called constructive interference. When the path difference of two beams of light is equal to the integral multiple of the wavelength, the constructive interference may occur.

The first light is light emitted from the package structure 100 in response to being reflected in the package structure 100 among light emitted from the light emitting element 200 (that is, the first light is light that is subjected to at least one reflection and at least one refraction in the package structure, and then emitted from the package structure). The second light is a light emitted from the package structure 100 without being reflected inside the package structure 100 among light emitted from the light emitting element 200. Further, a wavelength of the first light and a wavelength of the second light are the same, and may be both target wavelength.

In an exemplary embodiment, FIG. 2 is a path diagram of light that is emitted from a light emitting element and transmitted in the package structure shown in FIG. 1 according to an embodiment of the present disclosure. Arrows in solid lines refer to the first light, and arrows in dotted lines refer to the second light. The first inorganic layer 11 may adjust the path of the first light, such that the first light and the second light satisfy the interference condition and may interfere constructively since the path difference between the first light and the second light is the integral multiple of the wavelength, thereby increasing an intensity of the light emitted after passing through the package structure 100.

In summary, the package structure according to an embodiment of the present disclosure includes a first inorganic layer and a second inorganic layer covering the outer side of the light emitting element. The first inorganic layer is configured to adjust the path of the first light in the light emitted from the light emitting element, such that the first light and the second light in the light emitted from the light emitting element interfere constructively, thereby increasing the intensity of the light emitted after passing through the package structure and improving the light emitting efficiency of the light emitting element.

Optionally, in an embodiment of the present disclosure, the first light and the second light are both blue light, and the target wavelength may be a wavelength of the blue light. The first light and the second light are light emitted from the light emitting element for emitting blue light. At this time, the light emitting efficiency of the light emitting element for emitting blue light can be improved by the first inorganic layer 11. The wavelength of the blue light is in a range of 400 nm to 480 nm.

In an exemplary embodiment, the refractive index of the first inorganic layer 11 is in a range of [1.3, 1.7], and the refractive index of the second inorganic layer 12 is in a range of [1.6, 1.9]. The thickness of the first inorganic layer 11 is in a range of [20, 120] in a unit of nanometer, and the thickness of the second inorganic layer 12 is in a range of [500, 1000] in the unit of nanometer.

Optionally, FIG. 3 is a structural schematic diagram of a package structure according to another embodiment of the present disclosure. The package structure 100 may further include a third inorganic layer 13 and an organic layer 14 that are laminated and cover the outer side of the light emitting element 200. The third inorganic layer 13 is proximal to the light emitting element 200 relative to the organic layer 14, and the third inorganic layer 13 and the organic layer 14 are both proximal to the light emitting element 200 relative to the second inorganic layer 12. That is, the third inorganic layer 13, the organic layer 14, the second inorganic layer 12 and the first inorganic layer 11 in the package structure 100 are sequentially disposed along a direction F away from the light emitting element 200.

In an embodiment of the present disclosure, a refractive index of the third inorganic layer 13 is greater than a refractive index of the organic layer 14 and less than a refractive index of the second inorganic layer 12. In the package structure 100, the third inorganic layer 13 is a layer with high refractive index, the organic layer 14 is a layer with low refractive index, the second inorganic layer 12 is a layer with high refractive index and the first inorganic layer 11 is a layer with low refractive index, which are sequentially superposed along the direction away from the light emitting element 200. That is, the package structure 100 includes a plurality of layers with high refractive index and a plurality of layers with low refractive index which are arranged alternately, thereby further improving the light emitting efficiency of the light emitting element 200.

Optionally, the first inorganic layer 11 is made of silicon oxynitride, the second inorganic layer 12 is made of silicon nitride, and the third inorganic layer 13 is made of silicon oxynitride.

Optionally, the wavelength of the first light and the wavelength of the second light which are in the light emitted from the light emitting element 200 are the same, and may be both target wavelength. The first inorganic layer 11 is configured to adjust the path of the first light, such that the path difference between the path of the first light and the path of the second light is the integral multiple of the target wavelength. In this way, the first light and the second light satisfy the constructive interference condition, and may interfere constructively.

The package structure according to an embodiment of the present disclosure may be a thin-film package (TFE) structure.

In summary, the package structure according to an embodiment of the present disclosure includes a first inorganic layer and a second inorganic layer that are stacked and cover the outer side of the light emitting element. The first inorganic layer is configured to adjust the path of the first light in the light emitted from the light emitting element, such that the first light and the second light in the light emitted from the light emitting element interfere constructively, thereby increasing the intensity of the light emitted after passing through the package structure and improving the light emitting efficiency of the light emitting element.

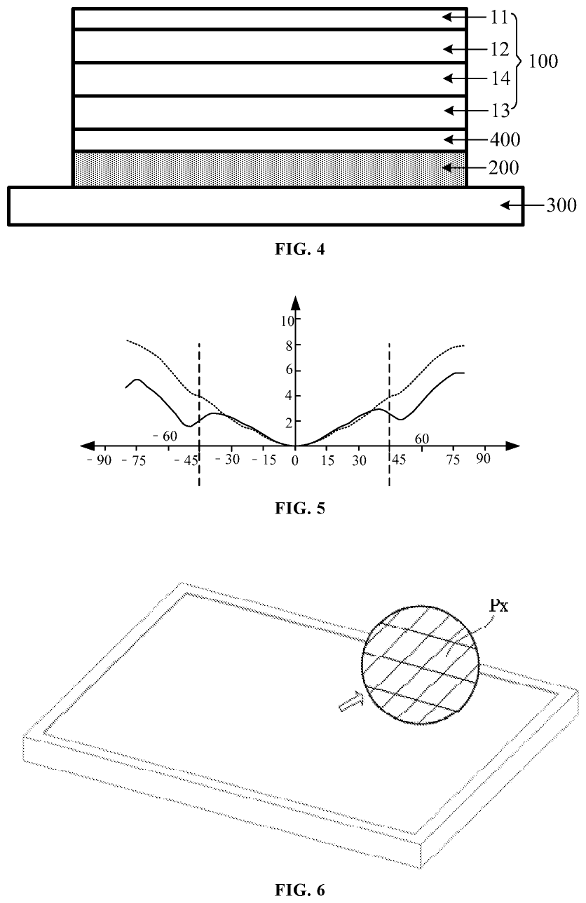

An embodiment of the present disclosure further provides a display panel. FIG. 4 is a structural schematic diagram of a display panel according to an embodiment of the present disclosure. The display panel may include:

a substrate 300, a light emitting element 200 disposed on the substrate 300, and a package structure 100 covering an outer side of the light emitting element 200. The package structure 100 is the package structure 100 as shown in FIG. 1 or the package structure 100 as shown in FIG. 3. In an exemplary embodiment, the light emitting element may be an OLED device.

Optionally, the display panel may further include a connection film layer 400 disposed between the light emitting element 200 and the package structure 100. The connection film layer 400 is configured to connect the light emitting element 200 and the package structure 100. The connection film layer 400 is made of lithium fluoride. The refractive index of the connection film layer 400 is less than the refractive index of the third inorganic layer 13 in the package structure 100.

In an embodiment of the present disclosure, the substrate 300 has a plurality of pixel regions, and each pixel region has three sub-pixel regions, that is, a red sub-pixel region, a green sub-pixel region and a blue sub-pixel region, respectively. The light emitting element 200 disposed on the substrate 300 may include a light emitting element for emitting red light disposed in the red sub-pixel region, a light emitting element for emitting green light disposed in the green sub-pixel region and a light emitting element for emitting blue light disposed in the blue sub-pixel region.

In the related art, a light emitting efficiency of blue light (also referred to as a blue light efficiency) of the OLED device for emitting blue light in the display panel is 130.5 cd/A, and only about 20% of the light emitted from the OLED device in the display panel may successfully penetrate through the package structure to be exported, resulting in a low light emitting efficiency of the display panel.

However, in an embodiment of the present disclosure, the first inorganic layer 11 in the package structure 100 may improve the blue light efficiency of the light emitting element for emitting blue light to 137.3 cd/A or more, which is improved by 5% or more compared with the blue light efficiency of the OLED device for emitting blue light in the related art. Thus, the light emitting efficiency of the light emitting element for emitting blue light is effectively improved. Further, a light emitting efficiency of the light emitting element for emitting red light in the display panel is substantially same as the light emitting efficiency of the OLED device for emitting red light in the related art, and a light emitting efficiency of the light emitting element for emitting green light is substantially same as the light emitting efficiency of the OLED device for emitting green light in the related art. Therefore, the package structure 100 in an embodiment of the present disclosure may effectively improve the light emitting efficiency of the display panel.

At the same time, the package structure 100 in an embodiment of the present disclosure may also reduce a probability of color deviation that occurs on the display panel.

In an exemplary embodiment, FIG. 5 is a comparative diagram of a relationship curve between a color deviation degree of a display panel and a viewing angle according to an embodiment of the present disclosure and a relationship curve between a color deviation degree of a display panel and a viewing angle in the related art. The solid line represents the relationship curve between the color deviation degree of the display panel and the viewing angle according to an embodiment of the present disclosure, and the dotted line represents the relationship curve between the color deviation degree of the display panel and the viewing angle in the related art.

An abscissa axis refers to the viewing angle in a unit of degrees, and 0 degrees represent that a viewing direction is perpendicular to a light emitting surface of the display panel; the viewing angle being a positive angle represents viewing the display panel from one side (e.g., the right side) of the display panel, and the viewing direction and the light emitting surface of the display panel are at an acute angle; the viewing angle being a negative angle represents viewing the display panel from the other side (e.g., the left side) of the display panel, and the viewing direction and the light emitting surface of the display panel are at the acute angle. A vertical axis refers to the degree of color deviation in a unit of just noticeable color difference (JNCD).

It may be known from FIG. 4 that when the viewing angle is greater than 45 degrees, the degree of color deviation of the display panel according to an embodiment of the present disclosure is obviously less than the degree of color deviation of the display panel in the related art. Therefore, the probability of color deviation that occurs on the display panel in an embodiment of the present disclosure is lower.

Optionally, in the display panel according to an embodiment of the present disclosure, the OLED device may be a phosphorescent OLED device. The phosphorescent OLED device is a device that emits light with a phosphorescent material, and its internal quantum efficiency (IQE, which is one of basic performance indicators of a photoelectric device) may be up to 100% theoretically and much higher than that of a fluorescent OLED device.

Certainly, in the display panel according to an embodiment of the present disclosure, the OLED device may also be a fluorescent OLED, which is not limited in the embodiment of the present disclosure.

In summary, in the display panel according to an embodiment of the present disclosure, the first inorganic layer covering the outer side of the light emitting element adjusts the path of the first light in the light emitted from the light emitting element, such that the first light and the second light in the light emitted from the light emitting element interfere constructively, thereby increasing the intensity of the light emitted after passing through the package structure, improving the light emitting efficiency of the light emitting element, and further improving the light emitting efficiency of the display panel. At the same time, the probability of color deviation that occurs on the display panel according to an embodiment of the present disclosure is low.

An embodiment of the present disclosure further provides a package method. FIG. 6 is a flowchart of a package method according to an embodiment of the present disclosure. The method is applicable to package of a light emitting element, so as to form a package structure at an outer side of the light emitting element. The method may include:

forming a plurality of package film layers at the outer side of the light emitting element. Such plurality of package film layers may form the package structure.

The plurality of package film layers include a first inorganic layer and a second inorganic layer that are laminated at the outermost side. The first inorganic layer is distal from the light emitting element relative to the second inorganic layer, a thickness of the first inorganic layer is less than a thickness of the second inorganic layer, and a refractive index of the first inorganic layer is less than a refractive index of the second inorganic layer.

The first inorganic layer is configured to adjust a path of first light, such that the first light and second light interfere constructively. The first light is light emitted from the package structure in response to being reflected inside the package structure among light emitted from the light emitting element (that is, the first light is light that is subjected to at least one reflection and at least one refraction in the package structure, and then emitted from the package structure), and the second light is light emitted from the package structure without being reflected inside the package structure among light emitted from the light emitting element.

Optionally, forming a plurality of package film layers at the outer side of the light emitting element includes: sequentially forming a third inorganic layer, an organic layer, a second inorganic layer and a first inorganic layer at the outer side of the light emitting element.

A refractive index of the third inorganic layer is greater than a refractive index of the organic layer and less than a refractive index of the second inorganic layer. In the package structure, the third inorganic layer is a layer with high refractive index, the organic layer is a layer with low refractive index, the second inorganic layer is a layer with high refractive index and the first inorganic layer is a layer with low refractive index, which are sequentially superposed along a direction away from the light emitting element. That is, the package structure includes a plurality of layers with high refractive index and a plurality of layers with low refractive index which are arranged alternately, thereby further improving a light emitting efficiency of the light emitting element.

In an exemplary embodiment, the third inorganic layer is formed at the outer side of the light emitting element by chemical vapor deposition (CVD); then, the organic layer is formed on the third inorganic layer by an ink-jet printing process; next, the second inorganic layer and the first inorganic layer are formed on the organic layer respectively by performing the CVD twice.

Optionally, in an embodiment of the present disclosure, the first light and the second light are both blue light, and a target wavelength may be a wavelength of the blue light. The first light and the second light are light emitted from the light emitting element for emitting blue light. At this time, the first inorganic layer 11 may effectively improve the light emitting efficiency of the light emitting element for emitting blue light. The wavelength of the blue light is in a range from 400 nm to 480 nm.

In an exemplary embodiment, the refractive index of the first inorganic layer 11 is in a range of [1.3, 1.7], and the refractive index of the second inorganic layer 12 is in a range of [1.6, 1.9]. The thickness of the first inorganic layer 11 is in a range of [20, 120] in a unit of nanometer, and the thickness of the second inorganic layer 12 is in a range of [500, 1000] in the unit of nanometer.

Optionally, the first inorganic layer is made of silicon oxynitride, the second inorganic layer is made of silicon nitride, and the third inorganic layer is made of silicon oxynitride.

Optionally, a wavelength of the first light and a wavelength of the second light in the light emitted from the light emitting element are the same, and may be both target wavelength. The first inorganic layer is configured to adjust the path of the first light, such that a path difference between the path of the first light and the path of the second light is an integral multiple of the target wavelength. In this way, the first light and the second light satisfy a constructive interference condition, and may interfere constructively.

A person skilled in the art may clearly understand that for convenience and simplicity of description, a specific principle of the package structure formed by the package method described above may be referred to the corresponding contents in the embodiments of the package structure described above, which is not repeated herein.

In summary, in the package method according to an embodiment of the present disclosure, a plurality of package film layers are formed at the outer side of the light emitting element, and the plurality of package film layers may include a first inorganic layer and a second inorganic layer that are laminated at the outermost side. The first inorganic layer is configured to adjust the path of the first light in the light emitted from the light emitting element, such that the first light and the second light in the light emitted from the light emitting element interfere constructively, thereby increasing the intensity of the light emitted after passing through the package structure and improving the light emitting efficiency of the light emitting element.

An embodiment of the present disclosure further provides a display device, and the display device may include the display panel as shown in FIG. 4. The display device may be any product or component with a display function such as electronic paper, a mobile phone, a tablet computer, a television, a display, a laptop, a digital photo frame and a navigator.

FIG. 6 is a structural schematic diagram of a display device according to an embodiment of the present disclosure. The display device includes any of the above display panels, and a display region of the display panel includes sub-pixel regions Px disposed in rows and columns. The above display region may have a plurality of data lines, each of the data lines may be disposed between two adjacent columns of sub-pixel regions Px to transmit an accessed data signal or test signal into each sub-pixel region Px.

It is to be noted that dimensions of layers and regions may be enlarged for clarity of illustration in the drawings. Further, it may be understood that when an element or layer is referred to as being “on” another element or layer, it may be directly on another element, or there may be an intermediate layer. In addition, it may be understood that when an element or layer is referred to as being “under” another element or layer, it may be directly under another element, or there may be one or more intermediate layers or elements. In addition, it may also be understood that when a layer or element is referred to as being “between” two layers or two elements, it may be the unique layer between the two layers or two elements, or there may also be one or more intermediate layers or elements. Similar reference symbols indicate similar elements throughout the specification.

In the present disclosure, terms “first” and “second” are only used for the purpose of descriptions and shall not be understood as indicating or implying relative importance. The term “a plurality of” refers to two or more, unless otherwise clearly defined.

Described above are merely optional embodiments of the present disclosure, and are not intended to limit the present disclosure. Within the spirit and principles of the present disclosure, any modifications, equivalent substitutions, improvements, and the like are all within the protection scope of the present disclosure.

1. A package structure, comprising a first inorganic layer and a second inorganic layer that are laminated and cover an outer side of a light emitting element; wherein
the first inorganic layer is distal from the light emitting element relative to the second inorganic layer, a thickness of the first inorganic layer is less than a thickness of the second inorganic layer, and a refractive index of the first inorganic layer is less than a refractive index of the second inorganic layer; and
the first inorganic layer is configured to cause a path difference between first light and second light to be an integral multiple of a target wavelength, wherein the first light is light emitted from the package structure in response to being reflected inside the package structure among light emitted from the light emitting element, and the second light is light emitted from the package structure without being reflected inside the package structure among light emitted from the light emitting element, a wavelength of the first light and a wavelength of the second light being both the target wavelength.

2. The package structure according to claim 1, wherein the first light and the second light are both blue light.

3. The package structure according to claim 1, wherein the refractive index of the first inorganic layer is in a range of [1.3, 1.7], and the refractive index of the second inorganic layer is in a range of [1.6, 1.9].

4. The package structure according to claim 1, wherein the thickness of the first inorganic layer is in a range from 20 nm to 120 nm, and the thickness of the second inorganic layer is in a range from 500 nm to 1000 nm.

5. The package structure according to claim 1, further comprising a third inorganic layer and an organic layer that are laminated and cover the outer side of the light emitting element; wherein the third inorganic layer is proximal to the light emitting element relative to the organic layer, and the organic layer is proximal to the light emitting element relative to the second inorganic layer.

6. The package structure according to claim 5, wherein a refractive index of the third inorganic layer is greater than a refractive index of the organic layer and less than a refractive index of the second inorganic layer.

7. The package structure according to claim 1, wherein the first inorganic layer is made of silicon oxynitride, and the second inorganic layer is made of silicon nitride.

8. The package structure according to claim 5, wherein the third inorganic layer is made of silicon oxynitride.

9. The package structure according to claim 1, wherein
the first light and the second light are both blue light;
the refractive index of the first inorganic layer is in a range of [1.3, 1.7], and the refractive index of the second inorganic layer is in a range of [1.6, 1.9];
the thickness of the first inorganic layer is in a range of 20 nm to 120 nm, and the thickness of the second inorganic layer is in a range of 500 nm to 1000 nm; and
the package structure further comprises a third inorganic layer and an organic layer that are laminated and cover the outer side of the light emitting element;
the third inorganic layer is proximal to the light emitting element relative to the organic layer, and the organic layer is proximal to the light emitting element relative to the second inorganic layer; and
a refractive index of the third inorganic layer is greater than a refractive index of the organic layer and less than a refractive index of the second inorganic layer.

10. A display panel, comprising: a substrate, a light emitting element disposed on the substrate, and a package structure covering an outer side of the light emitting element, wherein the package structure comprises a first inorganic layer and a second inorganic layer that are laminated and cover an outer side of a light emitting element; wherein
the first inorganic layer is distal from the light emitting element relative to the second inorganic layer, a thickness of the first inorganic layer is less than a thickness of the second inorganic layer, and a refractive index of the first inorganic layer is less than a refractive index of the second inorganic layer; and
the first inorganic layer is configured to cause a path difference between first light and second light to be an integral multiple of a target wavelength, wherein the first light is light emitted from the package structure in response to being reflected inside the package structure among light emitted from the light emitting element, and the second light is light emitted from the package structure without being reflected inside the package structure among light emitted from the light emitting element, a wavelength of the first light and a wavelength of the second light being both the target wavelength.

11. The display panel according to claim 10, further comprising: a connection film layer disposed between the light emitting element and the package structure.

12. The display panel according to claim 11, wherein the package structure comprises a third inorganic layer, an organic layer, a second inorganic layer, and a first inorganic layer that sequentially cover the outer side of the light emitting element along a direction distal from the substrate, wherein the third inorganic layer is proximal to the light emitting element relative to the organic layer and a refractive index of the third inorganic layer is greater than a refractive index of the connection film layer.

13. The display panel according to claim 12, wherein the refractive index of the third inorganic layer is greater than a refractive index of the organic layer and less than a refractive index of the second inorganic layer.

14. The display panel according to claim 12, wherein the first inorganic layer is made of silicon oxynitride, the second inorganic layer is made of silicon nitride, and the third inorganic layer is made of silicon oxynitride.

15. The display panel according to claim 12, wherein the third inorganic layer, the second inorganic layer and the first inorganic layer are formed by chemical vapor deposition.

16. The display panel according to claim 12, wherein the organic layer is formed by an ink-jet printing process.

17. The display panel according to claim 11, wherein the connection film layer is made of lithium fluoride.

18. The display panel according to claim 10, wherein the light emitting element comprises an organic light-emitting diode.

19. The display panel according to claim 10, further comprising a connection film layer disposed between the light emitting element and the package structure; wherein
the package structure comprises a third inorganic layer, an organic layer, a second inorganic layer, and a first inorganic layer that sequentially cover the outer side of the light emitting element along a direction distal from the substrate, wherein the third inorganic layer is proximal to the light emitting element relative to the organic layer and a refractive index of the third inorganic layer is greater than a refractive index of the connection film layer; and
the refractive index of the third inorganic layer is greater than a refractive index of the organic layer and less than a refractive index of the second inorganic layer.

20. A display device, comprising a display panel comprising: a substrate, a light emitting element disposed on the substrate, and a package structure covering an outer side of the light emitting element, wherein the package structure comprises a first inorganic layer and a second inorganic layer that are laminated and cover an outer side of a light emitting element; wherein
the first inorganic layer is distal from the light emitting element relative to the second inorganic layer, a thickness of the first inorganic layer is less than a thickness of the second inorganic layer, and a refractive index of the first inorganic layer is less than a refractive index of the second inorganic layer; and
the first inorganic layer is configured to cause a path difference between first light and second light to be an integral multiple of a target wavelength, wherein the first light is light emitted from the package structure in response to being reflected inside the package structure among light emitted from the light emitting element, and the second light is light emitted from the package structure without being reflected inside the package structure among light emitted from the light emitting element, a wavelength of the first light and a wavelength of the second light being both the target wavelength.
